(19) United States
(12) Patent Application Publication
(10) Pub. No.: US 2010/0213167 A1
(43) Pub. Date: Aug. 26, 2010

(54) METHOD OF PATTERNING VAPOUR DEPOSITION BY PRINTING

(76) Inventors: John R. Fyson, London (GB); Christopher L. Bower, Cambridgeshire (GB); John M. Higgins, Middlesex (GB)

Correspondence Address: EASTMAN KODAK COMPANY;PATENT LEGAL STAFF, 343 STATE STREET, ROCHESTER, NY, 14650-2201, US

(21) Appl. No.: 12/678,867

(22) PCT Filed: Sep. 9, 2008
(86) PCT No.: PCT/GB2008/003065

§ 371 Date: Mar. 18, 2010

(30) Foreign Application Priority Data
Sep. 26, 2007 (GB) 0718840.2

(51) Int. Cl. C23C 16/04

(52) U.S. Cl. 216/37

(57) ABSTRACT

A method of creating a patterned coated layer on a substrate comprises the steps of applying a pattern on the substrate by an additive process using a first material, depositing a second material by vapour deposition over the whole substrate area and removing the first material by treatment with a solvent.

### FIELD OF THE INVENTION

This invention relates to a method of patterning a substrate, in particular to a method of patterning by vapour deposition.

### BACKGROUND OF THE INVENTION

Chemical vapour deposition (CVD) and atomic layer deposition (ALD) are techniques of laying down a thin layer of material onto a substrate.

Chemical vapour deposition is a chemical process used to produce high-purity, high-performance solid materials. The process is often used in the semiconductor industry to produce thin films of dielectrics and semiconductors. In a typical CVD process, the substrate is exposed to one or more volatile precursors, which react and/or decompose on the substrate surface to produce the desired deposit.

Atomic Layer Deposition is a self-limiting, sequential surface chemistry that deposits conformal thin films of materials onto substrates of varying compositions. ALD is similar in chemistry to CVD except that the ALD reaction breaks the CVD reaction into two or more partial reactions, keeping the precursor materials separate during the reaction sequence.

ALD can be used to deposit several types of thin films, including various ceramics, from conductors to insulators.

When making components it is usually necessary to pattern the material being laid down. There are a number of ways recorded for doing this:

Deposit an even layer of the material and, using a photolithographic method, etch the unwanted sections of the layer away using a suitable etch chosen so as not to damage the remainder of the device (conventional art).

Put down a photoresist onto the substrate and image a profile in this resist using conventional lithography methods. Optionally treat this resist and then use CVD or ALD to coat a layer over the top. Scratch the top of the coating over the resist and treat with suitable solvent to remove the resist—the solvent percolating through the scratches. The coating falls off where the resist has been dissolved (see “Low-temperature atomic layer deposition lift-off method for microelectronic and nanoelectronic applications” Applied phys letters Vol 83, 12, pp2405, Biercuk, Monsma and Marcus).

Applying a mask to the substrate, patterning the mask, using ALD or CVD to coat a layer over the patterned mask and then removing the mask mechanically (see WO2006111766).

Using ALD and finding an inhibitor specific for the growing mechanism and printing this (see U.S. Pat. No. 7,030,001).

The first methods rely on the relatively complicated procedure of photolithography. This is a multi-step process usually consisting of the steps of spin-coating the resist, baking the resist, exposing the resist, baking the resist, developing the resist, washing and then drying it. In the third method the mask is patterned after being coated onto the substrate. This may be done using a photoresist method or perhaps more conveniently by ablating the mask with a suitably tuned laser.

There is a need to find a simpler way of patterning a layer of material.

### PROBLEM TO BE SOLVED BY THE INVENTION

The invention aims to provide a method of patterning a layer of material laid down by vapour deposition such as ALD or CVD which is simpler, more convenient and more flexible than methods of the prior art.

According to the present invention the pattern is applied using any additive process such as drawing with a pen or printing by any convenient method. This method may be ink-jet, flexography, offset lithography, silk-screen, gravure, or any other conventional printing technique. The ALD or CVD process is carried out to create the needed thickness over the whole patterned material and then the patterned material is washed in suitable solvent to leave the inverse pattern on the substrate.

### SUMMARY OF THE INVENTION

According to the present invention there is provided a method of creating a patterned coated layer on a substrate comprising the steps of applying a pattern on the substrate by an additive process using a first material, depositing a second material by vapour deposition over the whole substrate area and removing the first material by treatment with a solvent.

Preferably the second material is deposited by atomic layer deposition.

### ADVANTAGEOUS EFFECT OF THE INVENTION

The method of the present invention is simpler than the methods known in the prior art. Fewer steps are required in the process, resulting in a reduction in process and labour cost and reduction in waste due to possible errors.

Compared to the prior art methods the method of the present invention is: simpler, for example, does not require as many steps; more convenient, for example, uses readily available equipment, is easier to do, or uses more benign chemicals; and is more flexible, for example, potentially allows each pattern to be completely different, allows the patterning material or the thickness of the patterning material to be varied.

### BRIEF DESCRIPTION OF THE DRAWINGS

The invention will now be described with reference to the accompanying drawings in which:

FIG. 1 is a flow chart describing the steps of an atomic layer deposition process used in the present invention;

FIG. 2 is a cross sectional side view of an embodiment of a distribution manifold for atomic layer deposition that can be used in the present process;

FIG. 3 is a cross sectional side view of an embodiment of the distribution of gaseous materials to a substrate that is subject to thin film deposition; and

FIGS. 4A and 4B are cross sectional views of an embodiment of the distribution of gaseous materials schematically showing the accompanying deposition operation.

### DETAILED DESCRIPTION OF THE INVENTION

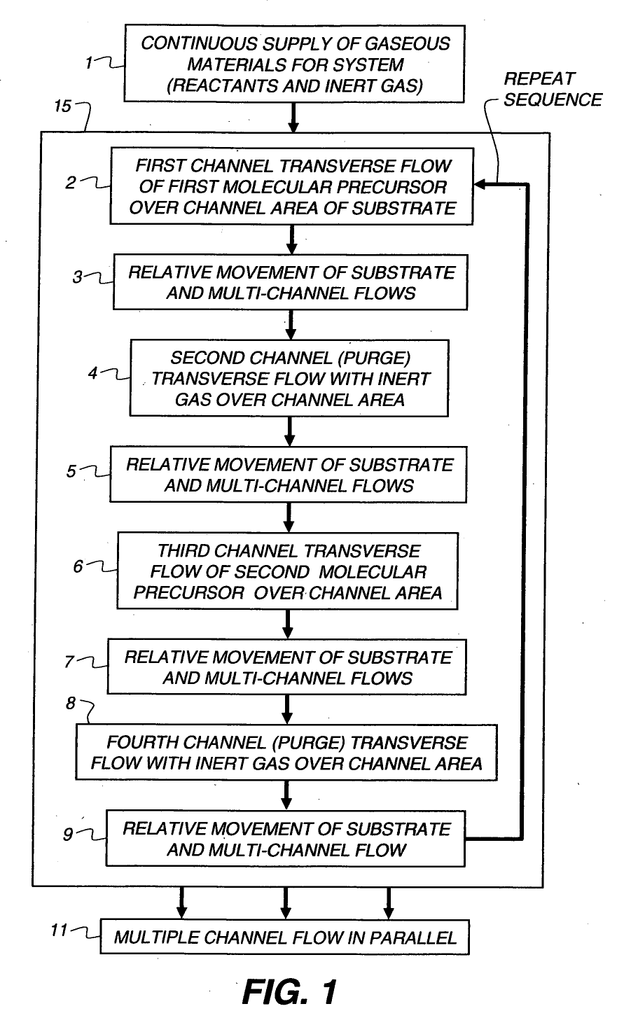

FIG. 1 is a generalized step diagram of a process for practicing the present invention. Two reactive gases are used, a first molecular precursor and a second molecular precursor. Gases are supplied from a gas source and can be delivered to the substrate, for example, via a distribution manifold. Metering and valving apparatus for providing gaseous materials to the distribution manifold can be used.

As shown in Step 1, a continuous supply of gaseous materials for the system is provided for depositing a thin film of material on a substrate. The Steps in Sequence 15 are sequentially applied. In Step 2, with respect to a given area of the substrate (referred to as the channel area), a first molecular precursor or reactive gaseous material is directed to flow in a first channel transversely over the channel area of the substrate and reacts therewith. In Step 3 relative movement of the substrate and the multi-channel flows in the system occurs, which sets the stage for Step 4, in which second channel (purge) flow with inert gas occurs over the given channel area. Then, in Step 5, relative movement of the substrate and the multi-channel flows sets the stage for Step 6, in which the given channel area is subjected to atomic layer deposition in which a second molecular precursor now transversely flows (substantially parallel to the surface of the substrate) over the given channel area of the substrate and reacts with the previous layer on the substrate to produce (theoretically) a monolayer of a desired material. Often in such processes, a first molecular precursor is a metal-containing compound in gas form (for example, a metallic compound such as titanium tetrachloride) and the material deposited is a metal-containing compound. In such an embodiment, the second molecular precursor can be, for example, a non-metallic oxidizing compound or hydrolyzing compound, e.g. water.

In Step 7, relative movement of the substrate and the multi-channel flows then sets the stage for Step 8 in which again an inert gas is used, this time to sweep excess second molecular precursor from the given channel area from the previous Step 6. In Step 9, relative movement of the substrate and the multi-channels occurs again, which sets the stage for a repeat sequence, back to Step 2. The cycle is repeated as many times as is necessary to establish a desired film or layer. The steps may be repeated with respect to a given channel area of the substrate, corresponding to the area covered by a flow channel. Meanwhile the various channels are being supplied with the necessary gaseous materials in Step 1. Simultaneous with the sequence of box 15 in FIG. 1, other adjacent channel areas are being processed simultaneously, which results in multiple channel flows in parallel, as indicated in overall Step 11.

The primary purpose of the second molecular precursor is to condition the substrate surface back toward reactivity with the first molecular precursor. The second molecular precursor also provides material as a molecular gas to combine with one or more metal compounds at the surface, forming compounds such as an oxide, nitride, sulfide, etc, with the freshly deposited metal-containing precursor.

The continuous ALD purge does not need to use a vacuum purge to remove a molecular precursor after applying it to the substrate.

Assuming that two reactant gases, AX and BY, are used, when the reaction gas AX flow is supplied and flowed over a given substrate area, atoms of the reaction gas AX are chemically adsorbed on a substrate, resulting in a layer of A and a surface of ligand X (associative chemisorptions) (Step 2). Then, the remaining reaction gas AX is purged with an inert gas (Step 4). Then, the flow of reaction gas BY, and a chemical reaction between AX (surface) and BY (gas) occurs, resulting in a molecular layer of AB on the substrate (dissociative chemisorptions) (Step 6). The remaining gas BY and by-products of the reaction are purged (Step 8). The thickness of the thin film can be increased by repeating the process cycle (steps 2-9).

Because the film can be deposited one monolayer at a time it tends to be conformal and have uniform thickness.

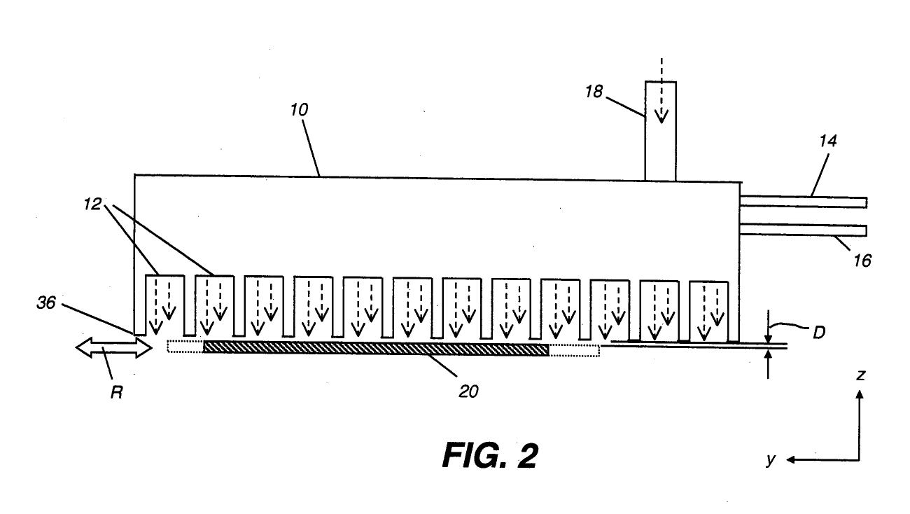

Referring now to FIG. 2, there is shown a cross-sectional side view of one embodiment of a distribution manifold 10 that can be used in the present process for atomic layer deposition onto a substrate 20. Distribution manifold 10 has a gas inlet port 14 for accepting a first gaseous material, a gas inlet port 16 for accepting a second gaseous material, and a gas inlet port 18 for accepting a third gaseous material. These gases are emitted at an output face 36 via output channels 12, having a structural arrangement described subsequently. The arrows in FIG. 2 refer to the diffusive transport of the gaseous material, and not the flow, received from an output channel. The flow is substantially directed out of the page of the figure.

Gas inlet ports 14 and 16 are adapted to accept first and second gases that react sequentially on the substrate surface to effect ALD deposition, and gas inlet port 18 receives a purge gas that is inert with respect to the first and second gases. Distribution manifold 10 is spaced a distance D from substrate 20, provided on a substrate support. Reciprocating motion can be provided between substrate 20 and distribution manifold 10, either by movement of substrate 20, by movement of distribution manifold 10, or by movement of both substrate 20 and distribution manifold 10. In the particular embodiment shown in FIG. 2, substrate 20 is moved across output face 36 in reciprocating fashion, as indicated by the arrow R and by phantom outlines to the right and left of substrate 20 in FIG. 2. It should be noted that reciprocating motion is not always required for thin-film deposition using distribution manifold 10. Other types of relative motion between substrate 20 and distribution manifold 10 could also be provided, such as movement of either substrate 20 or distribution manifold 10 in one or more directions.

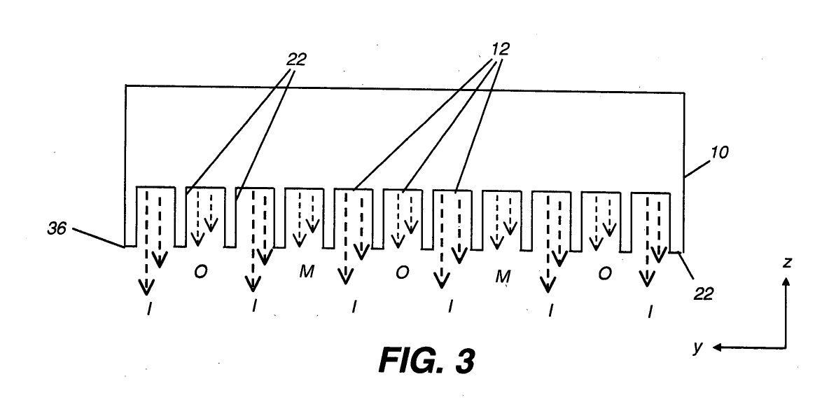

The cross-sectional view of FIG. 3 shows gas flows emitted over a portion of front face 36 of distribution manifold 10. In this particular arrangement, each output channel 12 is in gaseous flow communication with one of gas inlet ports 14,,16 or 18 seen in FIG. 2. Each output channel 12 delivers typically a first reactant gaseous material O, or a second reactant gaseous material M, or a third inert gaseous material I.

FIG. 3 shows a relatively basic or simple arrangement of gases. It is possible that a plurality of non-metal deposition precursors (like material O) or a plurality of metal-containing precursor materials (like material M) may be delivered sequentially at various ports in a thin-film single deposition. Alternately, a mixture of reactant gases, for example, a mixture of metal precursor materials or a mixture of metal and non-metal precursors may be applied at a single output channel when making complex thin film materials, for example, having alternate layers of metals or having lesser amounts of dopants admixed in a metal oxide material. The critical requirement is that an inert stream labeled I should separate any reactant channels in which the gases are likely to react with each other. First and second reactant gaseous materials O and M react with each other to effect ALD deposition, but neither reactant gaseous material O nor M reacts with inert gaseous material I.

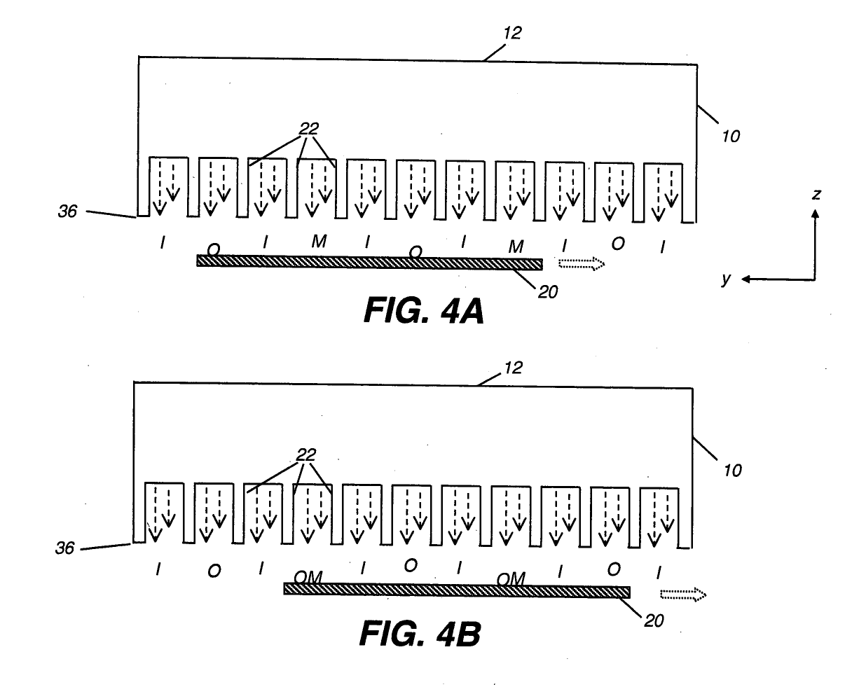

The cross-sectional views of FIGS. 4A and 4B show, in simplified schematic form, the ALD coating operation performed as substrate 20 passes along output face 36 of distribution manifold 10 when delivering reactant gaseous materials O and M. In FIG. 4A, the surface of substrate 20 first receives an oxidizing material from output channels 12 designated as delivering first reactant gaseous material O. The surface of the substrate now, contains a partially reacted form of material O, which is susceptible to reaction with material M. Then, as substrate 20 passes into the path of the metal compound of second reactant gaseous material M, the reaction with M takes place, forming a metallic oxide or some other thin film material that can be formed from two reactant gaseous materials.

As FIGS. 4A and 4B show, inert gaseous material I is provided in every alternate output channel 12, between the flows of first and second reactant gaseous materials O and M. Sequential output channels 12 are adjacent, that is, share a common boundary, formed by partitions 22 in the embodiments shown. Here, output channels 12 are defined and separated from each other by partitions 22 that extend perpendicular to the surface of substrate 20.

Notably, there are no vacuum channels interspersed between the output channels 12, that is, no vacuum channels on either side of a channel delivering gaseous materials to draw the gaseous materials around the partitions. This advantageous, compact arrangement is possible because of the innovative gas flow that is used. Unlike gas delivery arrays of earlier processes that apply substantially vertical (that is, perpendicular) gas flows against the substrate and should then draw off spent gases in the opposite vertical direction, distribution manifold 10 directs a gas flow (preferably substantially laminar in one embodiment) along the surface for each reactant and inert gas and handles spent gases and reaction by-products in a different manner. The gas flow used in the present invention is directed along and generally parallel to the plane of the substrate surface. In other words, the flow of gases is substantially transverse to the plane of a substrate rather than perpendicular to the substrate being treated.

The above described method and apparatus are one example of a vapour deposition process that can by used in the present invention. The invention works equally well using chemical vapour depositions.

### EXAMPLES

In all the examples ALD/CVD coating was carried out using apparatus similar to that described above. Either titanium dioxide or alumina was coated. For titanium dioxide, titanium tetrachloride was in one bubbler and water in the other. For alumina, a 1M solution of trimethylaluminium in heptane was in one bubbler and water in the other.

For both oxides, the flow rate of the carrier gas through the bubblers was 50 m1/min. The flow rate of diluting carrier gas was 300 ml/min for the water reactant and 150 m1/min for the titanium tetrachloride. The flow rate of the inert separator gas was 21/min Nitrogen was used for the carrier gas in all instances. A calibration run was run to determine the thickness versus number of substrate oscillations for both oxides.

### Example 1

A 63×63×1 mm piece of borosilicate glass was dipped half-way into Fluoropel PFC604A (trademark of Cytonix Corporation) fluoropolymer solution to give a half coated sample. The coating was allowed to dry and then approximately 100 nm alumina was coated over this by ALD, determined by number of platen oscillations (as determined by calibration). The coating of alumina over the fluoropolymer was heavily cracked but smooth on the plain glass sample. The sample was dipped in HFE 7500 solvent and gently rubbed with a rubber gloved hand. The sample was dried in air and the thickness of the coating of alumina in different positions was determined using an ellipsometer (Woolham). There was no residual alumina on the previously fluoropolymer coated section but the thickness was 105 nm on the area that had not been coated with fluoropolymer showing that the alumina coating was patterned by the fluoropolymer coating.

### Example 2

Example 1 was repeated except that titanium dioxide was used instead of alumina. The same result was obtained. Where the titanium dioxide was coated over the polymer none remained after washing in the HFE 7500 solvent as in example 1.

### Example 3

A mixture of 25% w/w Fluoropel P604A+75% perfluorodecalin was made up and loaded into a Dimatix ink-jet printer, as described in, the instruction book. A pattern of a series of lines was printed using the printer, having been given a suitable image to print, onto the same glass as in Example 1. The sample was allowed to dry and then was over coated with about 200 nm titanium dioxide. The coating was treated with HFE 7500 solvent as in example 1. The line pattern was reproduced in the titanium dioxide and could be seen by eye or under a microscope.

### Example 4

A small piece of vinyl tape was stuck to a glass plate which was then coated completely with PVA solution (that is, poly[vinyl alcohol], GH17R (Nippon Gohsei), as a 10 wt % solution) using an appropriate gravure bar to produce a wet laydown of about 50 micron. After the PVA coating had dried to produce a polymer layer, estimated to be about 5 microns, the tape was removed leaving a hole in the PVA coating, thereby creating a simple pattern. Over all this was coated a layer of about 100 nm titanium dioxide. The coating of titanium dioxide over the PVA was heavily cracked but smooth on the plain glass sample. The sample was then immersed in warm water and the PVA and the titanium dioxide covering it washed off. The thickness of the titanium dioxide remaining on the glass was determined by ellipsometry. It was found that there was no titanium dioxide where there had previously been PVA and a layer thickness of 97 nm where there had been none.

### Example 5

Example 4 was repeated replacing the PVA with PVP (10% polyvinylpyrollidone, PVP, K30 MW 10 k obtained from Fluka). As before, tape was used as a means of producing a simple pattern in the PVP layer. The same result was obtained i.e. titanium dioxide was found only on the areas that had not been covered with PVP.

### Example 6

Example 5 was repeated with different thicknesses of PVP, made by using different gravure bars to produce different wet lay downs of about 24, 12 and 6 microns. This gave estimated final thicknesses for the PVP masking layers of 2.4, 1.2 and 0.6 microns respectively. As before, tape was used as a means of producing a simple pattern in the PVP layer. Over this was coated alumina by ALD. The coating of alumina over the PVP was heavily cracked but smooth on the plain glass sample. The PVP and the alumina covering it were washed off. In all cases alumina was only found on the areas that had not been covered with PVP.

### Example 7

A PVP ink-jet ink was made up comprising a 10% K30, as used in example 5, 10% ethylene glycol and 1% Triton X-100. The latter two components were added to aid jetting. This was loaded into a Dimatix ink-jet printer as described in the instruction book. A pattern of a series of lines was printed using the printer, having been given a suitable image to print, onto the same glass as in Example 1. This was allowed to dry and then the sample was over coated with about 250 nm alumina. The coating was treated with warm water to remove the PVP and the alumina covering it. The line pattern was reproduced in the alumina and could be seen by eye or under a microscope.

### Example 8

A fluoropolymer ink formulation containing either Fluoropel P604A or P804A mixed with varying proportions of HFE 7500 to reduce the evaporation rate, was flexographically printed onto 5″ wide PET support using a Rotary Koater (RK Print Instruments, Royston, UK). A polymer-based flexographic plate with a pattern of various geometrical shapes was mounted on the printing head with a 67.5 mm diameter mechanically engraved chrome-plated Anilox roller (300 lines/inch) to supply the correct quantity of ink. The fluoropolymer ink was printed at 20 m/min, with the fans for the dryers switched on in order to extract some of the solvent fumes, but the printed base was not heated. The coating was allowed to dry and then a layer of approximately 100 nm titanium dioxide was coated over this by ALD, determined by number of platen oscillations (as determined by calibration). The coating of titania over the fluoropolymer was heavily cracked but smooth on the plain PET regions of the sample. The sample was dipped in HFE 7500 (3M) solvent and gently rubbed with a rubber gloved hand to remove the titania in the fluoropolymer coated regions.

In all the examples above patterning of the metal oxide layer was achieved by applying a printed polymer layer prior to vapour deposition. The metal oxide covering the polymer was then removed with the polymer by treatment with a solvent and some gentle rubbing.

The invention has been described in detail with reference to preferred embodiments thereof. It will be understood by those skilled in the art that variations and modifications can be effected within the scope of the invention.

1. A method of creating a patterned coated layer on a substrate comprising the steps of applying a pattern on the substrate by an additive process using a first material, depositing a second material by vapour deposition over the whole substrate area and removing the first material by treatment with a solvent.

2. A method as claimed in claim 1 wherein the second material is deposited by atomic layer deposition.

3. A method as claimed in claim 2 wherein the second material is deposited by simultaneously directing a series of gas flows along elongated channels such that the gas flows are substantially parallel to a surface of the substrate and substantially parallel to each other, whereby the gas flows are substantially prevented from flowing in the direction of the adjacent elongated channels, and wherein the series of gas flows comprises, in order, at least a first reactive gaseous material, inert purge gas, and a second reactive gaseous material, optionally repeated a plurality of times, wherein the first reactive gaseous material is capable of reacting with a substrate surface treated with the second reactive gaseous material.

4. A method as claimed in claim 1 wherein the second material is deposited by chemical vapour deposition.

5. A method as claimed in claim 1 wherein the first material is a swellable polymer.

6. A method as claimed in claim 5 wherein the first material is a fluoropolymer.

7. A method as claimed in claim 5 wherein the first material is a polyvinyl derivative.

8. A method as claimed in claim 1 wherein the first material is a water soluble ink.

9. A method as claimed in claim 1 wherein the first material is applied by an additive printing process.

10. A method as claimed in claim 9 wherein the first material is applied by inkjet printing.

11. A method as claimed in claim 9 wherein the first material is applied by flexographic printing.

12. A method as claimed in claim 8 wherein the first material is applied by means of a writing device containing water insoluble ink.

13. A method as claimed in claim 9 wherein the first material is applied in a roll to roll manner.

14. A method as claimed in claim 1 wherein the second material is a metal oxide, sulphide or nitride.

15. A method as claimed in claim 1 wherein the first material, when deposited as a layer, is such that it is mechanically different to the second material when deposited as a layer, such that the layer of second material forms cracks.
